(19) United States
(12) Patent Application Publication
(10) Pub. No.: US 2025/0344514 A1
(43) Pub. Date: Nov. 6, 2025

(54) SILICON CONTROLLED RECTIFIER WITH SCHOTTKY ANODE CONTACT

(71) Applicant: Soreq Nuclear Research Center, Yavne (IL)

(72) Inventors: Doron Cohen-Elias, Yavne (IL); Arie Raizman, Yavne (IL); Shoval Zoran, Yavne (IL); Amit Kesar, Yavne (IL)

(73) Assignee: Soreq Nuclear Research Center, Yavne (IL)

(21) Appl. No.: 18/869,856

(22) PCT Filed: May 29, 2023
(86) PCT No.: PCT/IB2023/055475

§ 371 Date: Nov. 27, 2024

Related U.S. Application Data
(60) Provisional application No. 63/346,869, filed on May 29, 2022.

(51) Int. Cl. H10D 89/60

(52) U.S. Cl. CPC H10D 89/713

(57) ABSTRACT

A semiconductor device includes a silicon controlled rectifier (SCR) that has a Schottky anode contact which is used for minority carrier injection.

### FIELD OF THE INVENTION

The present invention relates generally to silicon controlled rectifiers (SCRs) and particularly to an SCR with a Schottky anode contact.

### BACKGROUND OF THE INVENTION

Silicon controlled rectifiers (SCRs) are used widely in AC and DC motor control circuits, DC to AC inverters, alarm circuits and other high power circuits. The common SCR structure has four or five layers with alternating doping (NPN⁻P, NPN⁻NP), and for high voltages, a vertical structure with a few hundreds of microns thick N⁻ layer is required. This N⁻ layer is often the Si substrate and the other layers, namely cathode, gate, and anode, are a few or tens of micron thick made by long (a few hours) and high temperature (>1100° C.) diffusion processes on both sides of the substrate. These implant and diffusion processes on both side of the substrate make the process challenging and increase its cost.

### SUMMARY

The present invention seeks to provide an improved SCR with a Schottky anode contact, as is described hereinbelow.

In one embodiment, the SCR consists of two bipolar transistors, NPN and PNP, connected in positive feedback configuration, where the collector port of one transistor is connected to the base port of the other one. With this positive feedback connection, both electrons and holes are injected into the N⁻ layer and this reduces the SCR ON state resistance.

Injection of holes may be feasible when using an N-type Schottky contact, where a metal with a low energy barrier for holes is connected directly to the back side of the substrate, creating a Schottky anode contact.

The fabrication of an SCR with a Schottky anode contact is simpler when compared to prior art SCRs, with four or five layers, because with no back side implantation, the only implant and high temperature diffusion processes needed are for the gate and cathode layers.

The Schottky anode contact is used for minority carrier injection. The Schottky anode contact replaces the anode layer and the SCR device has three layers and the Schottky anode contact.

### BRIEF DESCRIPTION OF THE DRAWINGS

The present invention will be understood and appreciated more fully from the following detailed description taken in conjunction with the drawings in which:

FIG. 1 is a simplified schematic illustration of electrons and holes current components at the Schottky anode contact.

FIG. 2 is a simplified schematic illustration of the SCR device, having a Schottky anode contact.

FIGS. 3A-3B are simplified graphs of I-V characteristic of (FIG. 3A) 0.7 eV and (FIG. 3B) 0.9 eV Schottky barrier simulated SCRs.

FIG. 4 is a simplified graphical illustration of the simulated injection ratio at off and ON state for both 0.9 eV and 0.7 eV Schottky barrier simulated SCRs.

FIG. 5 is a simplified graphical illustration of the Gate-Cathode I-V characteristic of the fabricated SCR device.

FIG. 6 is a simplified graphical illustration of the I-V characteristic of the fabricated SCR device.

FIG. 7 is a simplified graphical illustration of the Gummel plot of the fabricated SCR device.

### DETAILED DESCRIPTION

A silicon controlled rectifier (SCR) with a Schottky anode contact was simulated, fabricated, and characterized. Without limitation, the fabricated SCR has a maximum blocking voltage of 125 V which is the voltage needed to deplete the high resistivity 525 μm substrates, having less than 10¹² cm⁻³ carrier density. As expected from SCRs, at gain above 1, the current reaches its maximum value which is limited by the measuring system. For having adequate ON resistance the Schottky contact need to have barrier height of ˜0.9 eV, as for Platinum-Silicon contacts.

The SCR consists of two bipolar transistors, NPN and PNP, connected in positive feedback configuration, where the collector port of one transistor is connected to the base port of the other one. With this positive feedback connection, both electrons and holes are injected into the N⁻ layer and reducing the SCR ON state resistance.

Injection of holes may be feasible when using an N-type Schottky contact, where a metal with a low energy barrier for holes is connected directly to the back side of the substrate, creating a Schottky anode contact.

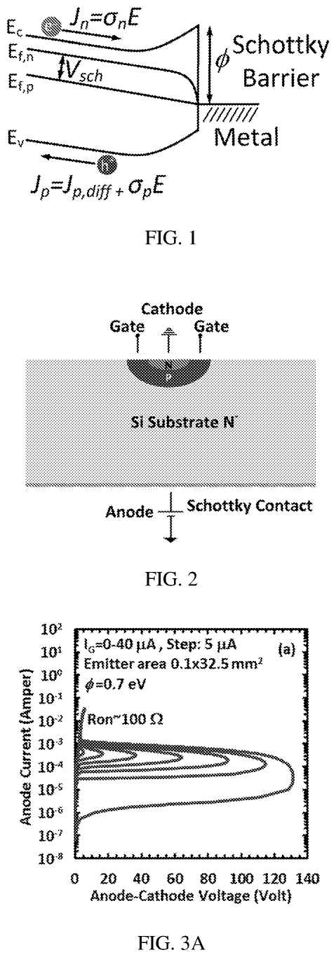

The electron current expression for Schottky contacts is given by:

$${J}_{n} = {J}_{0 , sch} [ exp \{ {qV}_{sh} / kT \} - 1 ] \qquad ( 1 )$$

where J_{0,sch}, q, Vₛₕ, k and T are the Schottky junction dark current, electron charge, the voltage applied on the Schottky junction, Boltzmann's constant and the temperature, respectively. In the semiconductor region Jₙ is a drift current and is equal to:

$${J}_{n} = {σ}_{n} E \qquad ( 2 )$$

where σₙ and E are the conductivity and the electrical field in the semiconductor neutral region. The hole current has both diffusion and drift components, as described in FIG. 1, and by using the drift diffusion equations the hole current density is given by:

$${J}_{p} ( {x}_{n} ) = \frac{{qD}_{p} [ p ( {x}_{n} ) - {p}_{0} ]}{W} + {σ}_{p} ( {x}_{n} ) E \\ where \qquad ( 3 )$$

$$p ( {x}_{n} ) = {p}_{0} exp \{ {qV}_{sh} / kT \} \qquad ( 4 )$$

$${σ}_{p} ( {x}_{n} ) = q {μ}_{p} p ( {x}_{n} ) \qquad ( 5 )$$

and Dₚ, W, p₀, σₚ, μₚ, and xₙ are the hole diffusion coefficient, length of the neutral region, holes density at equilibrium, holes conductivity, hole mobility and the end of the depletion region in the n-type semiconductor, respectively.

Further, when using the Einstein relation, Dₚ=kTμₚ/q

$${J}_{p} ( {x}_{n} ) = \frac{q {μ}_{p} {p}_{0}}{{J}_{0 , sch}} {J}_{n} ( \frac{kT}{qW} + E ) \qquad ( 6 )$$

Due to the hole barrier between the anode metal and the silicon substrate, the hole current density is negligible compared to the electron current density, Jₚ<<Jₙ, and the injection ratio, γ₀, of holes injected from the metal to the semiconductor can be written as:

$${γ}_{0} = {J}_{p} / ( {J}_{p} + {J}_{n} ) \approx \frac{q {μ}_{p} {p}_{0}}{{J}_{0 , sch}} ( \frac{kT}{qW} + E ) \\ For E ≪ kT / qW , {J}_{n} ≪ kT {μ}_{n} {N}_{D} / W \qquad ( 7 )$$

$${γ}_{0} \approx \frac{kT {μ}_{p} \frac{{p}_{0}}{{J}_{0 , sch}}}{W} = const \\ For E \approx kT / qW , \qquad ( 8 )$$

γ₀ increases linearly with the total current and for E>>KT/qW the hole current density is comparable to the electron current density and thus

$${γ}_{0} = {J}_{p} / ( {J}_{p} + {J}_{n} ) = {σ}_{p} / ( {σ}_{p} + {σ}_{n} ) \qquad ( 9 )$$

At the ON state, when the electron current increases and the semiconductor becomes intrinsic (n˜p), the injection ratio can be written as:

$${γ}_{0 , ON} = {μ}_{p} / ( {μ}_{p} + {μ}_{n} ) \qquad ( 10 )$$

For silicon substrates, at room temperature, having doping concentration below 10¹⁴ (cm⁻³) γ_{0,ON}≈0.2.

Using the Synopsys Sentaurus TCAD simulation tool, an SCR with anode collector contact was simulated. The simulated device had a silicon substrate with thickness of 512 μm and with a low n type background doping of 0.75×10¹² cm⁻³. The low background doping achieves low substrate conductivity and high holes injection ratio as seen in Eqs. (1-7). The cathode doping started with 10¹⁸ cm⁻³, at the Si-Air interface, and reached the substrate background doping at 1.5 μm depth. The gate doping started at the same interface with 10¹⁷ cm⁻³ and reached the substrate background doping at 5 μm depth. The cathode area was 3.25 mm² and the total device area was 58.5 mm².

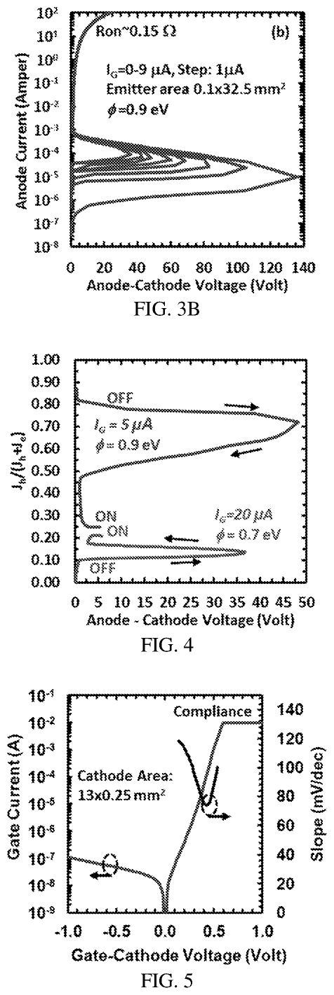

The Schottky contact barrier was set to 0.7 eV. A schematic diagram of the device is shown in FIG. 2. The simulated SCR I-V characteristic is shown in FIG. 3 with maximum off voltage of 130 Volt due to full depletion of the substrate and ON resistance of ˜100Ω. The ON-resistance, can be lower to less than 0.5Ω by using different metals with a higher Schottky barrier (>0.9 eV) such as Platinum. An ON-resistance comparison between SCRs with 0.7 eV and 0.9 eV anode Schottky barrier is presented in FIG. 4. For the 0.9 eV Schottky barrier a substrate background doping of 1.9×10¹² cm⁻³ was chosen in order to have the same off breakdown voltage as for the 0.7 eV Schottky barrier SCR. The injection ratios, γ₀, for 0.7 eV and 0.9 eV Schottky barrier SCRs are presented in FIG. 4. For both devices, γ₀ reached 0.2 at ON state when the substrates become intrinsic due to high electrons injection, Eq. 10. At OFF state γ₀ is increasing with applied voltage for the 0.7 eV Schottky barrier SCR, as expected from Eq. 7., however for the 0.9 eV Schottky barrier SCR, the hole barrier between the metal and the silicon substrate is ˜0.2 eV and the hole current is larger than the electron current hence γ₀ decreasing toward ˜0.2 for this device. For the same reason, of large hole current, at the maximum off voltage, of the 0.9 eV Schottky SCR, the 1.9×10¹² cm⁻³ doped substrate is not fully depleted, as in the 0.7 eV Schottky SCR.

SCRs with Schottky anode contact were fabricated using a planar diffusion source (PDS) of Boron nitride (BN) for boron diffusion, and Silicon Pyrophosphate (SiP₂O₇) for phosphorus diffusion. The gate boron diffusion was driven to 5 μm depth, and the emitter phosphorous diffusion was driven to 1 μm depth. For the Schottky contact gold was chosen due to its high (0.77-0.8 eV) Schottky barrier, suitable for holes injection. The silicon substrate was chosen with high resistivity (>10000 Ω-cm, N_{D}<10¹² cm⁻³) in order to have high electric field and high injection ratio, Eq. 7. With a thickness of 525 μm, the substrate is fully depleted when a more than 100 V bias is applied between the gate and the anode.

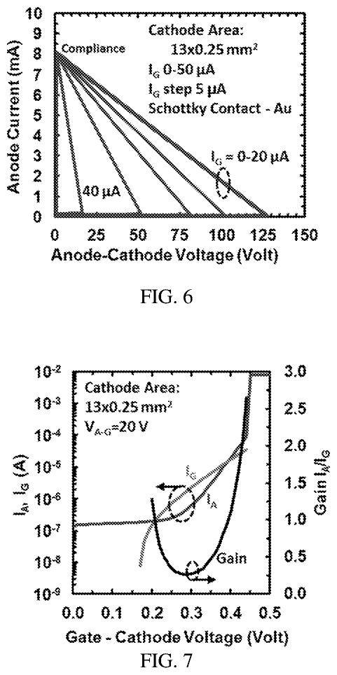

Using a Keysight B1505A Power Semiconductor Analyzer, Current-Voltage (I-V) characteristics were measured on wafer level, without dicing the devices. I-V characteristics of the Gate-Cathode junction showed adequate performances of 100 mA at 0.6 V with a minimum slope of less than 80 mV/dec (FIG. 5). FIG. 6 shows the SCR I-V characteristic and in good agreement with the simulation, the maximum OFF state voltage was 125 V and due to the low number of measuring points it was difficult to measure the ON-resistance. In the Gummel plot characteristic, FIG. 7, it is shown that at gains above 1 the SCR turns to ON state, as expected from rectifiers. The maximum ON current was limited to 8 mA by the system compliance.

In conclusion, the present invention describes an SCR with a Schottky anode contact. Without limitation, the SCR maximum voltage at OFF state is above 100 V. The maximum ON current was limited by the measurement system. An SCR with a Schottky anode contact has a simpler fabrication process. For acceptable ON-resistance (<1 Ohm) a platinum metal, with Schottky barrier of above 0.9 eV, may be used as the Schottky anode contact. For higher blocking voltages one can use thicker substrates with a higher doping level.

The Schottky anode contact is used for minority carrier injection. The Schottky anode contact replaces the anode layer and the SCR device has three layers and the Schottky anode contact.

What is claimed is:

1. A semiconductor device comprising:
a silicon controlled rectifier (SCR) comprising a Schottky anode contact which is used for minority carrier injection.

2. The semiconductor device according to claim 1, wherein said SCR has three layers and the Schottky anode contact is a fourth layer.

3. The semiconductor device according to claim 1, wherein said SCR has a maximum blocking voltage of 125 V for depleting a substrate having less than 10¹² cm⁻³ carrier density.

4. The semiconductor device according to claim 1, wherein said Schottky anode contact has a barrier height of ˜0.9 eV.

5. The semiconductor device according to claim 1, wherein said SCR comprises two bipolar transistors, NPN and PNP, connected in positive feedback configuration, wherein a collector port of one of said transistors is connected to a base port of another one of said transistors.

6. The semiconductor device according to claim 5, wherein both electrons and holes are injected into an N⁻ layer of the SCR.
